(19) United States
(12) Patent Application Publication
(10) Pub. No.: US 2024/0212992 A1
(43) Pub. Date: Jun. 27, 2024

(54) PLASMA PROCESSING APPARATUS AND METHOD

(71) Applicant: SAMSUNG ELECTRONICS CO., LTD., SUWON-SI (KR)

(72) Inventors: Changheon Lee, Suwon-si (KR); Sangki Nam, Suwon-si (KR); Kuihyun Yoon, Suwon-si (KR); Kiho Lee, Suwon-si (KR); Sangho Lee, Suwon-si (KR); Sangheun Lee, Suwon-si (KR); Jaemin Rhee, Suwon-si (KR); Junghyun Cho, Suwon-si (KR); Seoyeon Choi, Suwon-si (KR)

(21) Appl. No.: 18/453,378

(22) Filed: Aug. 22, 2023

(30) Foreign Application Priority Data
Dec. 23, 2022 (KR) 10-2022-0183218

(51) Int. Cl. H01J 37/32; H01L 21/683

(52) U.S. Cl. CPC H01J 37/32642; H01J 37/32715; H01J 37/3299; H01L 21/6833; H01J 2237/2007; H01J 2237/334

(57) ABSTRACT

Provided is a plasma processing apparatus including a substrate chuck in a chamber, a restriction ring surrounding an outer perimeter of the substrate chuck, a movable ring on the restriction ring, and an actuator configured to move the movable ring, wherein grooves formed in the restriction ring are opened or closed by movement of the movable ring. In addition, provided is a plasma processing method using the plasma processing apparatus.

### CROSS-REFERENCE TO RELATED APPLICATION

This application is based on and claims priority under 35 U.S.C. § 119 to Korean Patent Application No. 10-2022-0183218, filed on Dec. 23, 2022, in the Korean Intellectual Property Office, the disclosure of which is incorporated by reference herein in its entirety.

### TECHNICAL FIELD

The inventive concept relates to a plasma processing apparatus and method. More particularly, the inventive concept relates to a plasma processing apparatus and method for controlling the plasma distribution inside a plasma chamber.

### DESCRIPTION OF RELATED ART

A process of manufacturing a semiconductor device may include a plasma process including plasma-assisted deposition, plasma etching, plasma cleaning, and the like. As the miniaturization and integration of semiconductor devices has advanced, the process of manufacturing the semiconductor device has become more sensitive. For example, even a minute error in a plasma process may significantly affect the quality and yield of semiconductor products.

Factors related to the plasma process that may affect yield in the process of manufacturing the semiconductor device may include uniformity of a process between a central region and an edge region of a wafer. For example, radius-dependent changes in process evaluation elements, such as orthogonality of a plasma etching profile, are factors that may affect a total yield, as well as the quality of elements of the semiconductor device.

That is, one parameter for improving the reliability of the plasma process may be the density-radius distribution of plasma. Accordingly, a need exists for an apparatus and method to improve the uniformity of the density-radius distribution of plasma in a plasma process.

### SUMMARY

The inventive concept provides a plasma processing apparatus and method for actively controlling a plasma distribution and density inside a plasma chamber.

The inventive concept provides a plasma processing apparatus.

According to an aspect of the inventive concept, there is provided a plasma processing apparatus including a substrate chuck in a chamber, a restriction ring surrounding an outer perimeter of the substrate chuck, a movable ring on the restriction ring, and an actuator configured to move the movable ring, wherein grooves formed in the restriction ring are opened or closed by movement of the movable ring.

According to another aspect of the inventive concept, there is provided a plasma processing apparatus including a substrate chuck in a chamber and configured to receive a substrate, a restriction ring surrounding an outer perimeter of the substrate chuck, a movable ring having a ring shape surrounding a side partitioning wall of the restriction ring at an outer side portion of the restriction ring, and an actuator configured to move the movable ring, wherein grooves formed in the restriction ring are opened or closed by movement of the movable ring.

The inventive concept provides a plasma processing method.

According to another aspect of the inventive concept, there is provided a plasma processing method including loading a substrate on a substrate chuck of a chamber, injecting process gas into the chamber, and processing the substrate by supplying radio frequency (RF) power to the chamber, wherein the processing of the substrate includes performing, at least once, an operation of adjusting a position of a movable ring disposed on a restriction ring surrounding an outer perimeter of the substrate chuck.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view schematically illustrating a plasma processing apparatus according to an embodiment;

FIG. 2 is a bottom view of a movable ring used in the plasma processing apparatus of FIG. 1, according to an embodiment;

FIG. 3A, FIG. 3B, FIG. 4A, FIG. 4B, and FIG. 4C are bottom views and perspective views for describing an operation of the movable ring of FIG. 2;

FIG. 5 is a bottom view of a movable ring used in the plasma processing apparatus of FIG. 1, according to another embodiment;

FIG. 6A and FIG. 6B are bottom views for describing an operation of the movable ring of FIG. 5;

FIG. 7 is a cross-sectional view schematically illustrating a plasma processing apparatus according to another embodiment;

FIG. 8 is a perspective view of a movable ring used in the plasma processing apparatus of FIG. 7, according to an embodiment;

FIG. 9A, FIG. 9B, and FIG. 9C are perspective views for describing an operation of the movable ring of FIG. 8;

FIG. 10 is a cross-sectional view schematically illustrating a plasma processing apparatus according to another embodiment;

FIG. 11 is a perspective view of a movable ring used in the plasma processing apparatus of FIG. 10, according to an embodiment;

FIG. 12A, FIG. 12B, and FIG. 12C are perspective views for describing an operation of the movable ring of FIG. 11;

FIG. 13 is a perspective view of a movable ring used in the plasma processing apparatus of FIG. 10, according to another embodiment;

FIG. 14A, FIG. 14B, and FIG. 14C are perspective views for describing an operation of the movable ring of FIG. 13; and

FIG. 15 illustrates simulation results showing the distribution of a plasma density and an ion flux according to the volume of an internal space surrounded by a restriction ring of a plasma chamber, according to the technical idea of the inventive concept.

### DETAILED DESCRIPTION

Hereinafter, embodiments are described in detail with reference to the accompanying drawings. Like reference numerals in the drawings denote like elements, and thus their repetitive description may be omitted.

Embodiments may allow various kinds of change or modification and various changes in form, and specific embodiments will be illustrated in drawings and described in detail in the detailed description. However, it should be understood that the specific embodiments do not limit the inventive concept to a specific disclosing form but include every modified, equivalent, or replaced one within the disclosed spirit and technical scope. In the detailed description, when it is determined that a specific description of relevant well-known features may obscure the essentials of the inventive concept, a detailed description thereof may be omitted.

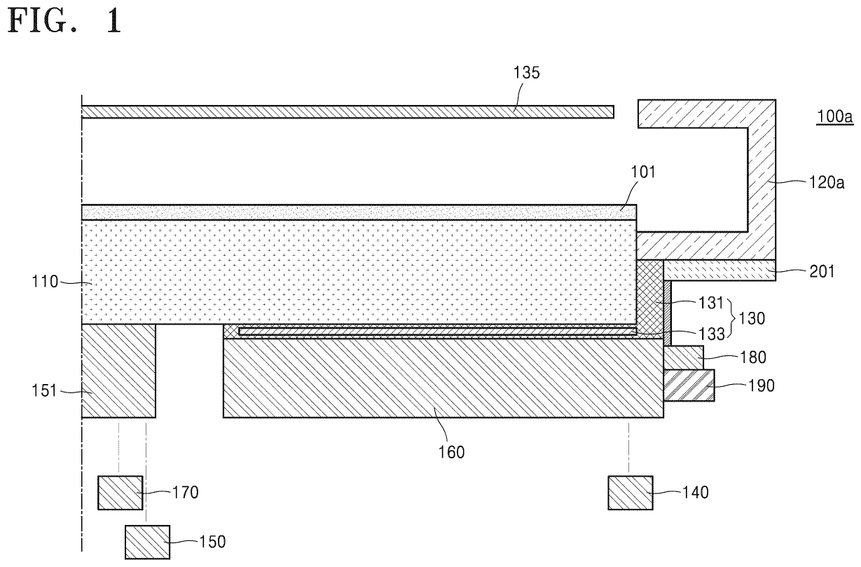

FIG. 1 is a cross-sectional view schematically illustrating a plasma processing apparatus 100a according to an embodiment.

Referring to FIG. 1, the plasma processing apparatus 100a may include a substrate chuck 110, a restriction ring 120a, an edge block 130, a controller 140, a power supply 150, an insulating plate 160, a plasma generator 170, a sensor 180, an actuator 190, and a movable ring 201.

The plasma processing apparatus 100a may be a plasma etching apparatus capable of processing a substrate 101 in a process chamber, e.g., performing a plasma etching process, using plasma. The plasma processing apparatus 100a may be configured to perform a semiconductor device manufacturing process. The plasma processing apparatus 100a may include a capacitively coupled plasma source, an inductively coupled plasma source, a microwave plasma source, a remote plasma source, or the like. The plasma processing apparatus 100a may perform a substrate processing process, such as, plasma annealing, etching, plasma-enhanced chemical vapor deposition, plasma-enhanced atomic layer deposition, physical vapor deposition, or plasma cleaning.

The plasma processing apparatus 100a may perform, for example, a reactive ion etching process. The reactive ion etching process is an example of a dry etching process. The reactive ion etching process may be used to etch a substrate or a thin film in a low-pressure chamber by species (radicals or ions) excited by a high frequency radio frequency (RF) power source. The reactive ion etching process may be performed by bombardment of energetic ions in combination with a physical action and a chemical action of a chemically active species. The reactive ion etching process may include etching of an insulating layer, which may include silicon oxide, etching of a metal material, and etching of a doped or undoped semiconductor material. The plasma processing apparatus 100a may process the substrate 101 by using generated plasma.

The substrate 101 may be a wafer, e.g., a silicon wafer. The substrate 101 may include a semiconductor element, such as germanium (Ge), or a compound semiconductor, such as silicon carbide (SiC), gallium arsenide (GaAs), indium arsenide (InAs), or indium phosphide (InP). The substrate 101 may have a silicon on insulator (SOI) structure. The substrate 101 may include a buried oxide layer. The substrate 101 may include a conductive region, e.g., an impurity-doped well. The substrate 101 may have various device isolation structures, such as a shallow trench isolation (STI) structure for isolating doped wells from each other. The substrate 101 may have a first surface and a second surface. The first surface may be an active surface and the second surface may be an inactive surface opposite to the first surface. The second surface of the substrate 101 may face the substrate chuck 110. A material layer, e.g., an oxide or nitride layer, may be formed on the substrate 101.

The process chamber may be, for example, a plasma chamber. The process chamber may be formed of a metal, such as aluminum. The process chamber has an approximately cylindrical shape. The process chamber may provide a processing space for processing the substrate 101. The process chamber may isolate the processing space from an outside and thus control process parameters, such as pressure, temperature, partial pressure of a processing gas, and plasma density. An internal space of the process chamber may have cylindrical symmetry.

According to embodiments, the process chamber may provide a plasma region. The plasma region may be understood to be a space in which plasma may be formed while processing the substrate 101, and a space, such as a sheath region, that may be affected by plasma. The plasma region may be understood to be a space among the substrate chuck 110, an upper electrode 135, and the restriction ring 120a.

The upper electrode 135 may be spaced apart from the substrate chuck 110. The upper electrode 135 may be disposed above the substrate chuck 110. The upper electrode 135 may face the substrate chuck 110. The upper electrode 135 may form a ceiling of the process chamber. The upper electrode 135 may be fixed to a ceiling of the process chamber.

The upper electrode 135 may be connected to the power supply 150. The power supply 150 may generate a radio-frequency (RF) power. The power supply 150 may supply the RF power to the upper electrode 135 via an impedance matcher (not shown). The upper electrode 135 may be connected to a gas supply source (not shown) configured to supply process gas. For example, the upper electrode 135 may be an electrode with a shower head configuration.

The upper electrode 135 having the shower head configuration may uniformly provide process gas into the process chamber. The upper electrode 135 may have an annular side wall and a disc-shaped spray plate. The side wall of the upper electrode 135 may be fixedly coupled to the process chamber to protrude downward from an upper wall of the process chamber, and the spray plate may be fixedly coupled to a lower end of the side wall of the upper electrode 135. A plurality of spray holes may be formed in the entire area of the spray plate. The spray plate of the upper electrode 135 may be disposed in an internal space of the process chamber. The spray plate of the upper electrode 135 may face the substrate chuck 110. Process gas supplied through the gas supply source (not shown) may be sprayed to the internal space of the process chamber through the plurality of spray holes of the upper electrode 135.

The process chamber may further include an exhaust device. The exhaust device may be configured to discharge material of a process. For example, the exhaust device may discharge a reactant, debris, processing gas, and plasma after processing the substrate 101.

The substrate chuck 110 may be disposed on the insulating plate 160. The substrate chuck 110 may support the substrate 101 thereon. The substrate chuck 110 may be an electrostatic chuck (ESC) configured to fix the substrate 101 by an electrostatic force. The substrate chuck 110 may fix the substrate 101 by using the electrostatic force. The substrate chuck 110 may be provided to an inside of the process chamber configured to perform a semiconductor manufacturing process using plasma, e.g., etching, deposition, cleaning, and the like.

The power supply 150 may supply the RF power to the substrate chuck 110. The power supply 150 may apply source power or bias power to the substrate chuck 110 via an RF rod 151. The substrate chuck 110 may function as an electrode configured to generate plasma in the process chamber during a plasma processing process.

The restriction ring 120a may be used to control plasma formation and protect a chamber wall of the plasma processing apparatus 100a. The restriction ring 120a may be disposed on the edge block 130. The restriction ring 120a disposed on the edge block 130 may surround the outer perimeter of the substrate 101. In a top view, the restriction ring 120a may have a ring shape surrounding the substrate 101.

The restriction ring 120a may include grooves. The plasma region surrounded by the restriction ring 120a may be connected to a space provided outside the restriction ring 120a through the grooves of the restriction ring 120a. Each of the grooves of the restriction ring 120a may be a radial straight groove. For example, each of the grooves of the restriction ring 120a may extend radially and linearly. The grooves of the restriction ring 120a may be spaced apart from each other at a uniform interval. In this case, if the interval between the grooves of the restriction ring 120a is less than 0.1 cm, air current passing through the grooves may be interrupted, and if the interval is greater than 2 cm, plasma may leak out from the plasma region. Therefore, the grooves of the restriction ring 120a may be spaced apart from each other at an interval between about 0.1 cm to about 2 cm. For example, the grooves of the restriction ring 120a may be formed in a lower portion of the restriction ring 120a. However, a shape, an interval, and a position of the grooves of the restriction ring 120a are not limited to those described herein.

At least a portion of the restriction ring 120a may be disposed at a lower level than an upper surface of the substrate 101. An inner portion of the restriction ring 120a may be disposed below an edge region of the substrate 101.

The RF power supplied to the substrate chuck 110 may be provided to the restriction ring 120a via the substrate chuck 110 and/or the edge block 130. By providing the RF power to the restriction ring 120a via the substrate chuck 110 and/or the edge block 130, an electric field formation region in the process chamber may extend up to a region near the restriction ring 120a, and plasma generated in the process chamber may be extended.

In some embodiments, the restriction ring 120a may include a dielectric, an insulator, a semiconductor, or a combination thereof. For example, the restriction ring 120a may include silicon (Si), SiC, carbon (C), or a combination thereof.

A cross-section of the restriction ring 120a on a vertical plane passing through a central axis of the restriction ring 120a may correspond to a C shape. The restriction ring 120a of the plasma processing apparatus 100a of FIG. 1 may have a C-shaped cross-section on a vertical plane passing through the central axis. For example, in the cross-section, the restriction ring 120a may include an upper cover plate and a lower cover plate facing in a vertical direction, and a side wall extending in the vertical direction between the upper cover plate and the lower cover plate. The restriction ring 120a may be used as a component of a capacitively coupled plasma processing chamber. For example, an inner surface of the restriction ring 120a may provide an extended plasma restriction zone surrounding a gap between a lower electrode 133. The lower electrode 133 may support a semiconductor substrate during plasma processing in the process chamber.

The movable ring 201 may be disposed on the restriction ring 120a. For example, the movable ring 201 may be disposed beneath the restriction ring 120a.

The edge block 130 may include a body 131 and the lower electrode 133.

The body 131 of the edge block 130 may be a portion forming the exterior of the edge block 130. The body 131 of the edge block 130 may cover at least a portion of a side surface of the substrate chuck 110 and cover at least a portion of a lower surface of the substrate chuck 110. The lower surface of the substrate chuck 110 may be a surface opposite to a surface of the substrate chuck 110 on which the substrate 101 may be loaded. The body 131 of the edge block 130 may support the restriction ring 120a thereon.

In some embodiments, the body 131 of the edge block 130 may include a dielectric, an insulator, a semiconductor, or a combination thereof. For example, the body 131 may include alumina (Al₂O₃), quartz, yttrium oxide (Y₂O₃), SiC, silicon oxide (SiO₂), or a combination thereof.

The lower electrode 133 may be provided to the inside of the body 131 of the edge block 130. The lower electrode 133 may be separated from the substrate chuck 110. For example, the lower electrode 133 may be separated from the substrate chuck 110 with a portion of the body 131 therebetween. When RF power is applied to the substrate chuck 110, a certain capacitance may be formed between the substrate chuck 110 and the lower electrode 133, and the lower electrode 133 may be RF-coupled to the substrate chuck 110. In some embodiments, the lower electrode 133 may have a plate shape extending along the lower surface of the substrate chuck 110.

In some embodiments, the upper electrode 135 and the lower electrode 133 may include aluminum (Al), copper (Cu), nickel (Ni), gold (Au), silver (Ag), or a combination thereof.

The controller 140 may control an RF coupling operation between the substrate chuck 110 and the lower electrode 133 of the edge block 130. For example, the controller 140 may include a variable capacitor connected to the lower electrode 133 of the edge block 130, and the lower electrode 133 of the edge block 130 may be connected to ground via the variable capacitor. When RF power is applied to the substrate chuck 110, the controller 140 may adjust a magnitude of the RF power applied to the lower electrode 133 of the edge block 130 by adjusting a capacitance of the variable capacitor.

The sensor 180 may sense the plasma distribution inside the process chamber. When the sensor 180 senses the plasma distribution, the plasma generator 170 may control the amount of plasma introduced into the process chamber based on a result output by the sensor 180. The plasma generator 170 may include a gas supply configured to supply plasma generation source gas into the process chamber and electrodes (e.g., a power supply configured to supply power to the upper electrode 135 and the lower electrode 133) configured to generate plasma. The plasma generator 170 may include the power supply 150.

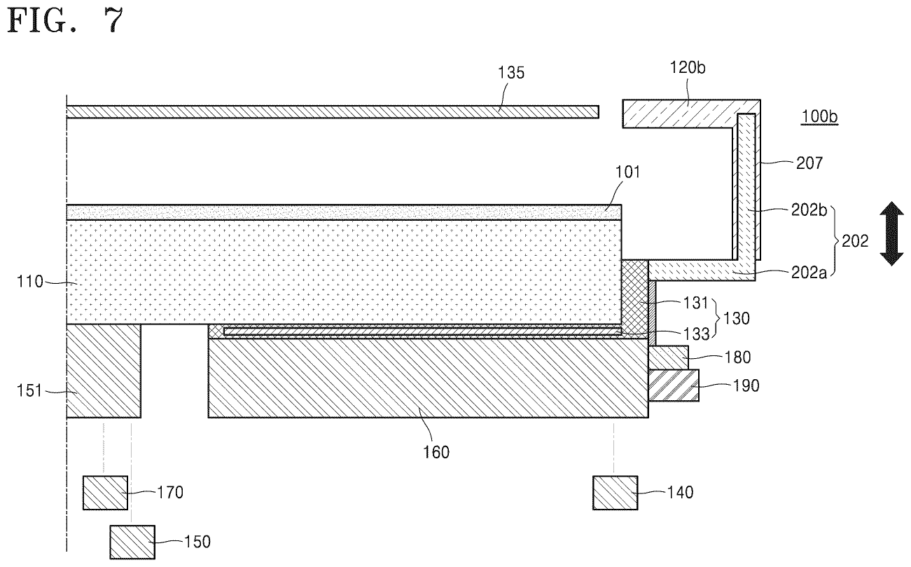

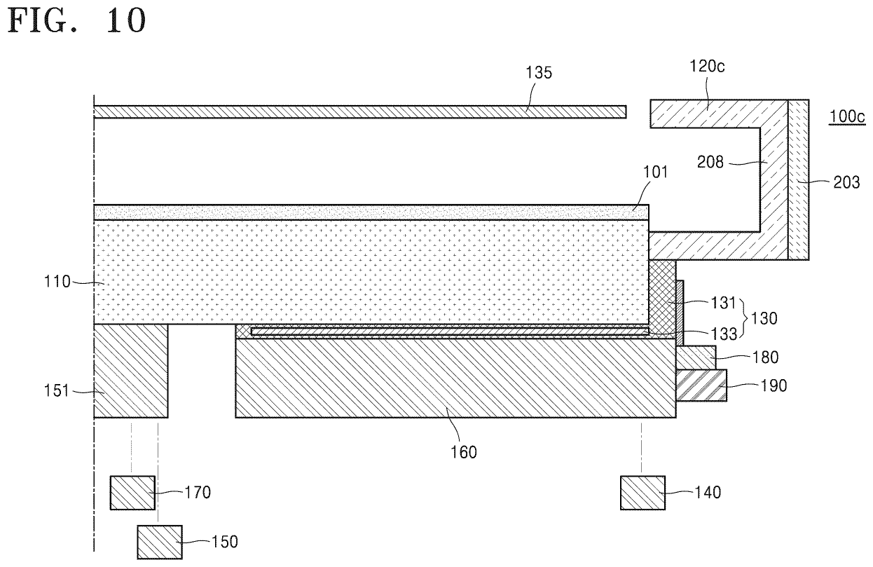

The actuator 190 may move the movable ring 201. Although FIG. 1, FIG. 7, and FIG. 10 show that the actuator 190 at a lower end of the process chamber, this is only illustrative, and the position of the actuator 190 is not limited thereto. For example, the actuator 190 may be adjacent to the upper electrode 135 at an upper end of the process chamber. The plasma processing apparatus 100a may include the sensor 180 configured to sense the plasma distribution inside the process chamber. The plasma generator 170 may control an amount of plasma generated in the process chamber, based on a sensing result of the sensor 180. The plasma generator 170 may control, in real-time, an amount of plasma generated in the process chamber, based on a sensing result of the sensor 180. The plasma distribution inside the process chamber may be monitored by the sensor 180, and the plasma generator 170 may adjust the generation of plasma in the process chamber based on the result output by the sensor 180.

Although not shown in FIG. 1, the plasma processing apparatus 100a may include a motion controller configured to control the motion of the movable ring 201. The motion controller may include a memory and a processor. The processor may be configured to process a command stored in the memory or an external control signal. The motion controller may be implemented by hardware, firmware, software, or a combination thereof. For example, the motion controller may include a computing device, such as a workstation computer, a desktop computer, a laptop computer, or a tablet computer. The motion controller may include a controller, a processor, such as a microprocessor, a central processing unit (CPU), or a graphics processing unit (GPU), a processor configured by software, or exclusive hardware or firmware. The motion controller may be implemented by, for example, a general-purpose computer or application-specific hardware, such as a digital signal processor (DSP), a field programmable gate array (FPGA), or an application specific integrated circuit (ASIC).

According to embodiments, an operation of the motion controller may be implemented by instructions stored in a machine-readable medium, which may be readable and executable by one or more processors. Herein, the machine-readable medium may include a mechanism configured to store and/or transmit information in a form readable by a machine (e.g., a computing device). For example, the machine-readable medium may include read-only memory (ROM), random access memory (RAM), a magnetic disk storage medium, an optical storage medium, flash memory devices, an electrical, optical, acoustic, or other form of propagation signal (e.g., a carrier, an infrared signal, a digital signal, or the like), or another signal.

Firmware, software, a routine, or instructions may be configured cause a processor to perform the operations described with respect to the motion controller or a process to be described below. However, this is for convenience of description, and the aforementioned operations of the memory and the processor may be implemented in a computing device, a processor, a controller, or another device configured to execute firmware, software, a routine, instructions, or the like.

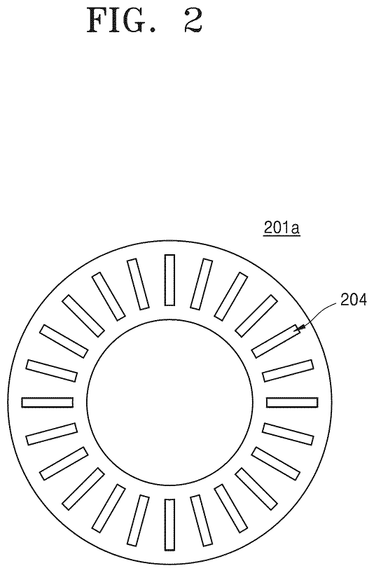

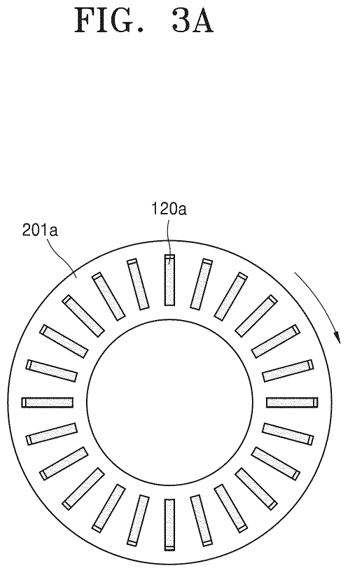

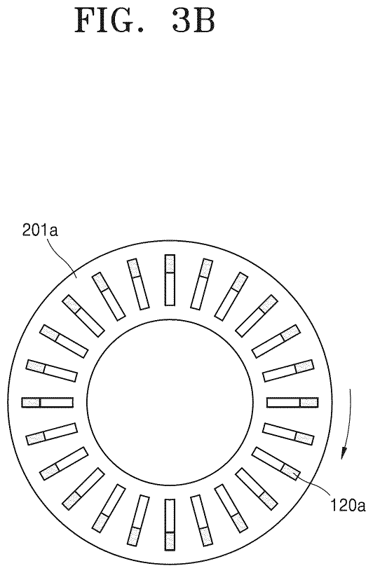

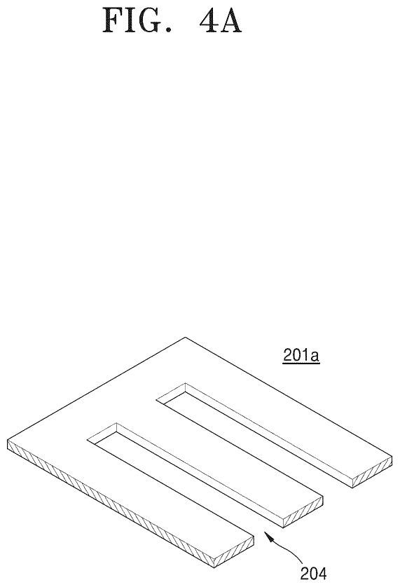

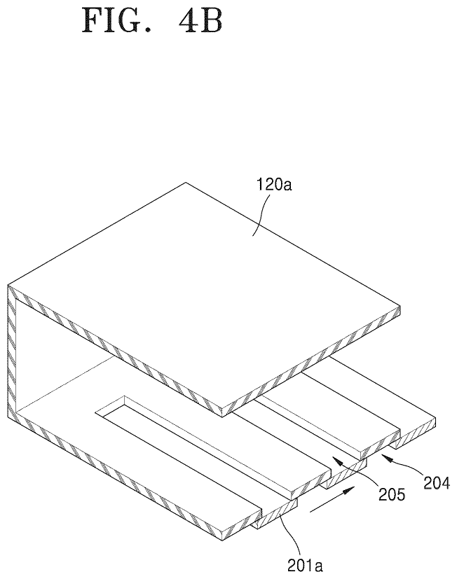

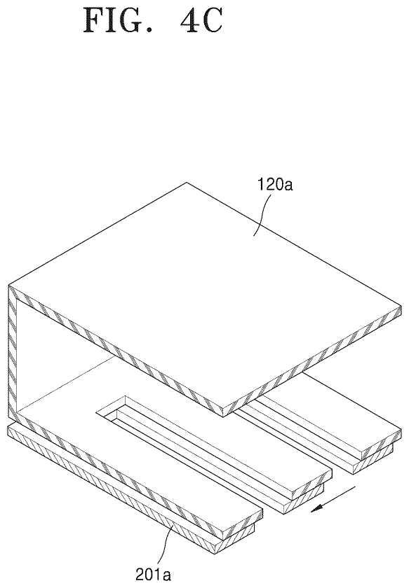

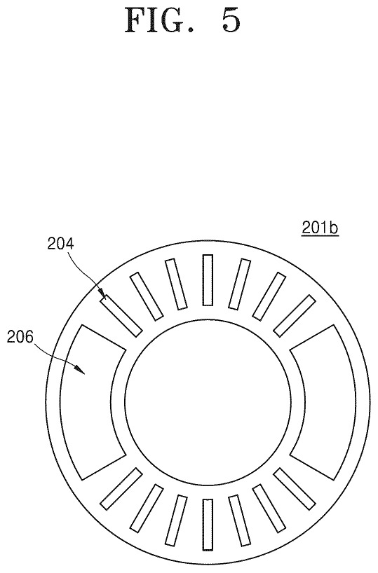

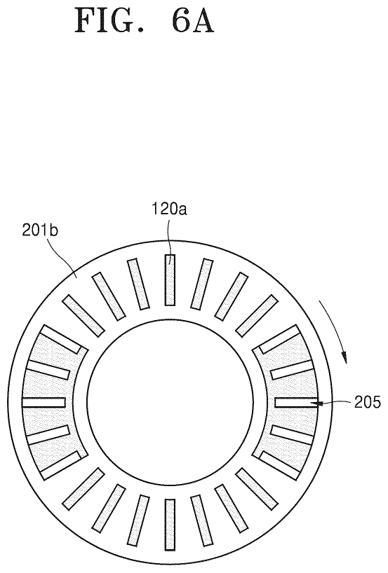

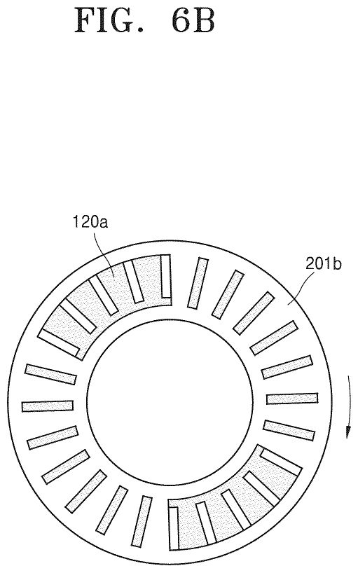

Operations of the actuator 190 and the movable ring 201 of the plasma processing apparatus 100a shown in FIG. 1 are described in detail below with reference to FIG. 2, FIG. 3A, FIG. 3B, FIG. 4A, FIG. 4B, FIG. 4C, FIG. 5, FIG. 6A, and FIG. 6B.

FIG. 2 is a bottom view of a movable ring 201a used in the plasma processing apparatus 100a of FIG. 1, according to an embodiment, and FIG. 3A, FIG. 3B, FIG. 4A, FIG. 4B, and FIG. 4C are bottom views and perspective views for describing an operation of the movable ring 201a of FIG. 2.

Referring to FIG. 2, the movable ring 201a may have a ring shape. The movable ring 201a may extend along the side surface of the substrate chuck 110. The movable ring 201a may vertically overlap a lower portion (e.g., a lower cover plate of the restriction ring 120a) of the restriction ring 120a. The movable ring 201a may include first grooves 204 penetrating through the movable ring 201a. Each of the first grooves 204 of the movable ring 201a may be a radial straight groove. For example, each of the first grooves 204 of the movable ring 201a may extend radially and linearly. The first grooves 204 of the movable ring 201a may be spaced apart from each other at a uniform interval. In this case, if the uniform interval is less than 0.1 cm, air current passing through the first grooves 204 may be interrupted, and if the uniform interval is greater than 2 cm, plasma may leak out from the plasma region. Therefore, the first grooves 204 of the movable ring 201a may be spaced apart from each other at an interval between about 0.1 cm to about 2 cm.

FIG. 3A and FIG. 3B are bottom views of the movable ring 201a beneath the restriction ring 120a. The restriction ring 120a may include second grooves 205 (see FIG. 4B) penetrating through the restriction ring 120a. Herein, the second grooves 205 may be radial straight grooves having a certain interval. The second grooves 205 of the restriction ring 120a may be spaced apart from each other at a uniform interval. The second grooves 205 of the restriction ring 120a may be spaced apart from each other at an interval of between about 0.1 cm to about 2 cm.

Referring to FIG. 3A and FIG. 3B, an open-close ratio of a lower surface of the restriction ring 120a covered by the movable ring 201a may be adjusted by rotating the movable ring 201a. While rotating the movable ring 201a, the second grooves 205 of the restriction ring 120a may be gradually closed by the movable ring 201a or gradually opened to the outside by vertically overlapping the first grooves of the movable ring 201a. Although FIG. 3A and FIG. 3B show only a case where the movable ring 201a rotates clockwise, the movable ring 201a may rotate counterclockwise. The movable ring 201a may be rotated by the actuator 190 (see FIG. 1).

FIG. 4A is a perspective view schematically illustrating a portion of the movable ring 201a shown in FIG. 2. Referring to FIG. 4B and FIG. 4C, by rotating the movable ring 201a, the open-close ratio of the lower surface of the restriction ring 120a may change, thereby resulting in active control of the flow and density of air current in the internal space of the process chamber surrounded by the restriction ring 120a.

FIG. 3A and FIG. 4B illustrate a closed condition. In the closed condition, the first grooves 204 of the movable ring 201a and the second grooves 205 of the restriction ring 120a may be alternately disposed. In the closed condition, the restriction ring 120a may close the lower surface of the restriction ring 120a. As illustrated in FIG. 3A, even in the closed condition, a portion of the first grooves 204 of the movable ring 201a may be open.

FIG. 3B and FIG. 4C illustrate an open condition. In the open condition, the second grooves 205 of the restriction ring 120a are at least partially aligned with the first grooves 204 of the movable ring 201a. As illustrated in FIG. 3B, even in the open condition, a portion of the first grooves 204 of the movable ring 201a may be closed by a portion of the movable ring 201a. FIG. 5 is a bottom view of a movable ring 201b used in the plasma processing apparatus 100a of FIG. 1, according to an embodiment, and FIGS. 6A and 6B are bottom views for describing an operation of the movable ring 201b of FIG. 5.

Referring to FIG. 5, the movable ring 201b may alternately include sets of the first grooves 204 and a fan-shaped groove 206. That is, the movable ring 201b may include grooves with different sizes and shapes. The movable ring 201b may have an asymmetrical structure as shown in FIG. 5, thereby improving process performance at a local position of a plasma field inside the process chamber. The asymmetrical structure of the movable ring 201b according to the technical idea of the inventive concept is not limited to the embodiment shown in FIG. 5.

Referring to FIG. 6A and FIG. 6B, an open-close ratio of the lower surface of the restriction ring 120a covered by the movable ring 201b may be adjusted by rotating the movable ring 201b. Although FIG. 6A and FIG. 6B show only a case where the movable ring 201b rotates clockwise, the movable ring 201b may rotate counterclockwise. The movable ring 201b may be rotated by the actuator 190 (see FIG. 1). In particular, the movable ring 201b may have an asymmetrical structure alternately including sets of the first grooves 204 and the fan-shaped groove 206, which may enable an asymmetrical control of the flow and density of air current in the internal space of the process chamber surrounded by the restriction ring 120a according to rotation of the movable ring 201b.

FIG. 7 is a cross-sectional view schematically illustrating a plasma processing apparatus 100b according to another embodiment. Hereinafter, a description made with respect to the plasma processing apparatus 100a of FIG. 1 may be omitted, and differences therefrom are mainly described.

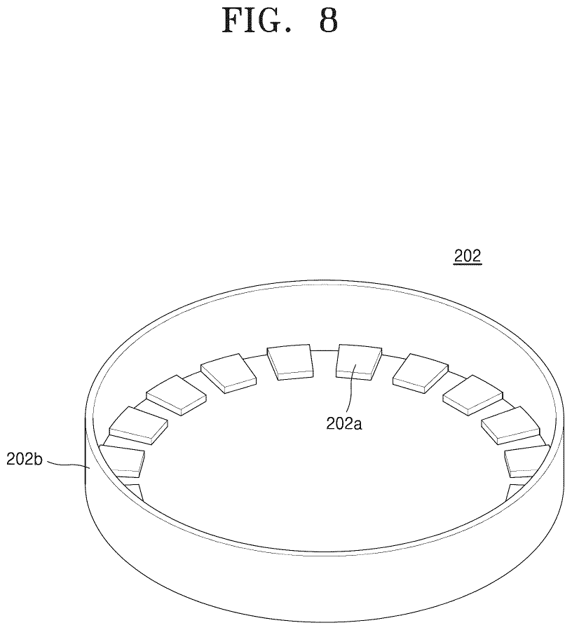

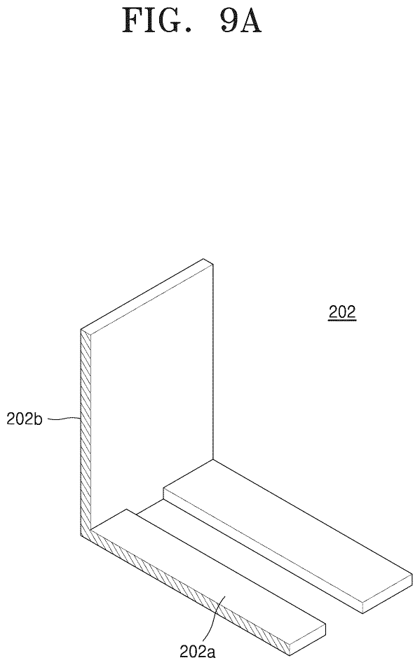

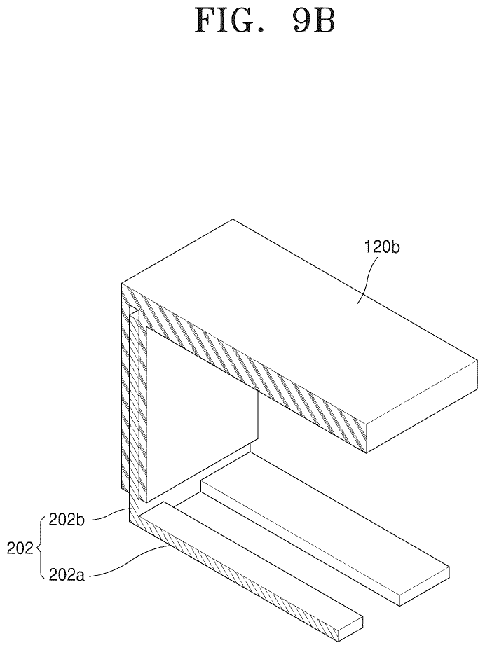

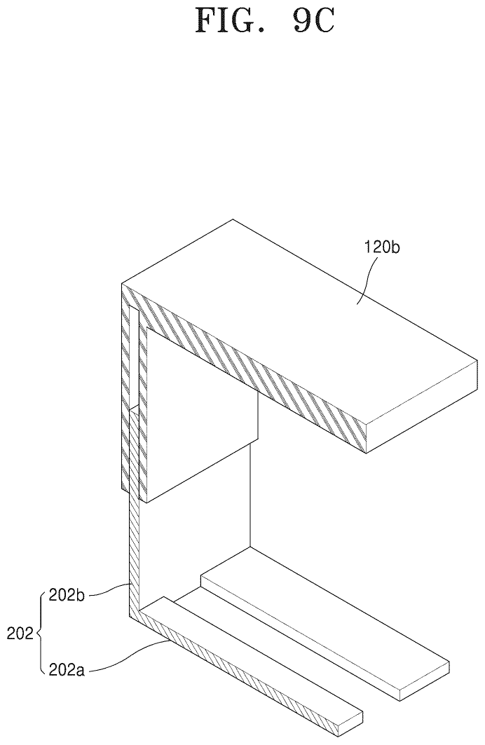

In addition, operations of the actuator 190 and a movable ring 202 of the plasma processing apparatus 100b shown in FIG. 7 are described in detail herein with reference to FIG. 8, FIG. 9A, FIG. 9B, and FIG. 9C.

Referring to FIG. 7, the movable ring 202 may include a lower surface 202a and a side wall 202b. The movable ring 202 may have an L-shaped cross-section on a vertical plane passing through a central axis of the movable ring 202. The lower surface 202a of the movable ring 202 may have a ring shape extending along the side surface of the substrate chuck 110 and include radial straight grooves at a certain interval. The interval may be between about 0.1 cm to about 2 cm.

At least a portion of the side wall 202b of the movable ring 202 may be formed on at least a portion of a first side partitioning wall 207 of a restriction ring 120b. For example, the portion of the side wall 202b of the movable ring 202 may be formed on an inside or an outside of at least a portion of a first side partitioning wall 207 of a restriction ring 120b.

At least a portion of the side wall 202b of the movable ring 202 may cooperate with at least a portion of a first side partitioning wall 207 of a restriction ring 120b, and the portion of the side wall 202b of the movable ring 202 may be formed on an inside and an outside of at least a portion of a first side partitioning wall 207 of a restriction ring 120b. For example, a portion of the side wall 202b of the movable ring 202 may fit within a portion of the first side partitioning wall 207 of a restriction ring 120b. More particularly, the lower surface of the first side partitioning wall 207 of the restriction ring 120b may have a gap configured to receive the side wall 202b of the movable ring 202. The lower surface of the first side partitioning wall 207 of the restriction ring 120b may extend to the lower surface 202a at the side wall 202b.

According to an embodiment, the restriction ring 120b may include the first side partitioning wall 207 and an upper cover. An area defined by the side partitioning wall of the restriction ring 120b may be open at a bottom portion thereof, and when the movable ring 202 is moved upward and downward by the actuator 190, a portion or the entirety of the side wall 202b of the movable ring 202 may be inserted into and withdrawn from the first side partitioning wall 207 of the restriction ring 120b. the lower surface of the first side partitioning wall 207 of the restriction ring 120b may have an open structure, and the restriction ring 120b may have, in a lower side thereof, a groove configured to connect the plasma region with an external space of the restriction ring 120b.

In other words, the restriction ring 120b may include an upper cover plate, and an inner side wall and an outer side wall each connected to the upper cover plate and together forming the first side partitioning wall 207. The inner side wall and the outer side wall of the restriction ring 120b may form the gap therebetween for receiving the side wall 202b of the movable ring 202. That is, in the restriction ring 120b, the inner side wall may extend to surround the outer perimeter of the substrate 101, and the outer side wall may extend to surround the inner side wall. In the restriction ring 120b, the gap may be formed between the inner side wall and the outer side wall. In addition, the movable ring 202 may include a side wall inserted into the gap between the inner side wall and the outer side wall, and a plurality of lower cover plates at a lower end of the side wall. In the movable ring 202, the plurality of lower cover plates may be separated from each other in a circumferential direction of the side wall. The movable ring 202 may be configured to be vertically moved by the actuator 190, and during the vertical movement of the movable ring 202, the side wall of the movable ring 202 may vertically move along the inner side wall or the outer side wall of the restriction ring 120b.

FIG. 8 is a perspective view of the movable ring 202 of FIG. 7, according to an embodiment. FIG. 9A is a perspective view schematically illustrating a portion of the movable ring 202 shown in FIG. 8, and FIG. 9B and FIG. 9C are perspective views for describing an operation of the movable ring 202.

Referring to FIG. 9B and FIG. 9C, when the movable ring 202 moves upward and downward, the side wall 202b of the movable ring 202 may be inserted into and withdrawn from the gap of the first side partitioning wall 207 of the restriction ring 120b so that an internal volume of a space surrounded by the restriction ring 120b may be changed. By the change of the internal volume, the density of plasma may be effectively controlled.

FIG. 10 is a cross-sectional view schematically illustrating a plasma processing apparatus 100c according to another embodiment. A restriction ring 120c of FIG. 10 may correspond to the restriction ring 120a of FIG. 1. Hereinafter, a description made with respect to the plasma processing apparatus 100a of FIG. 1 may be omitted, and differences therefrom are mainly described.

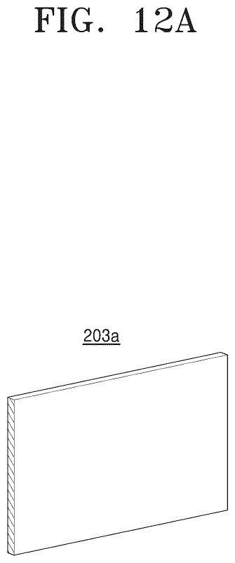

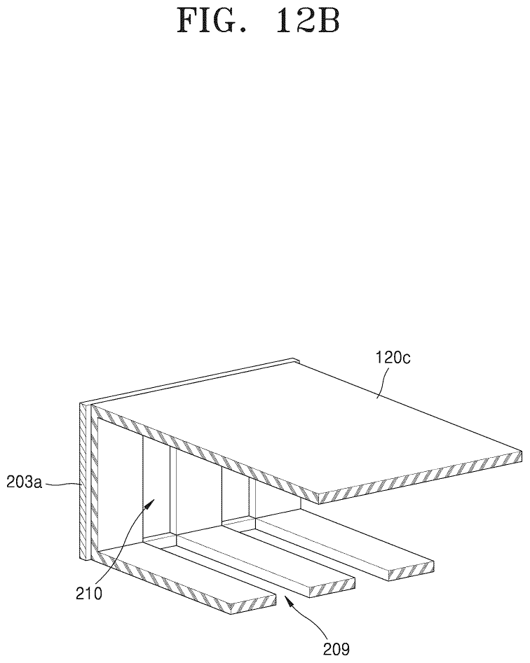

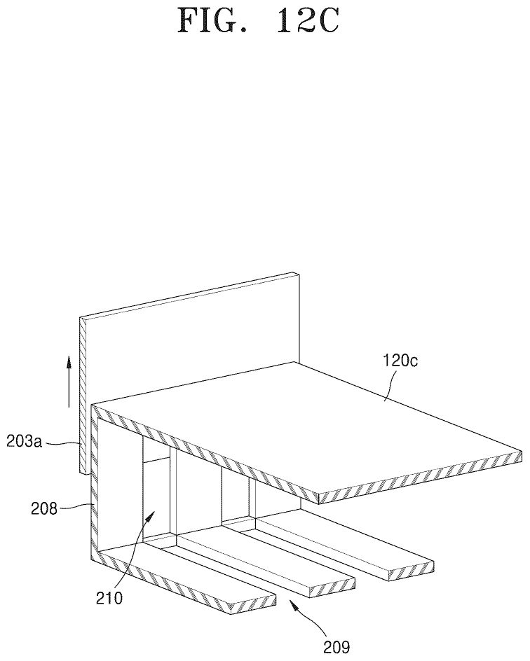

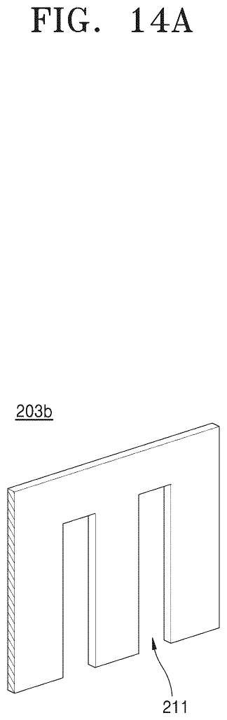

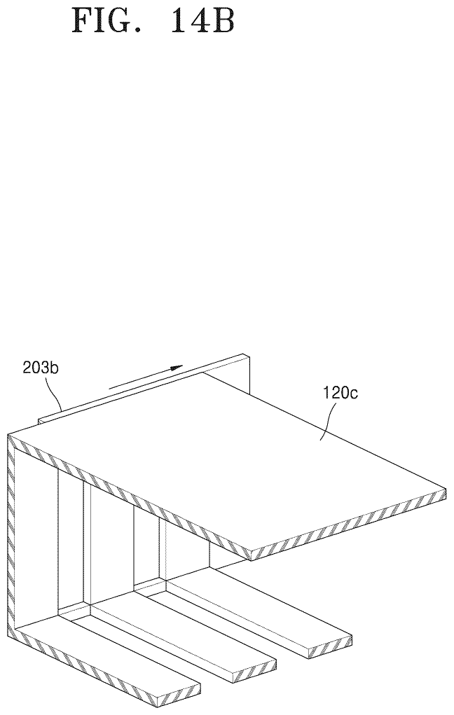

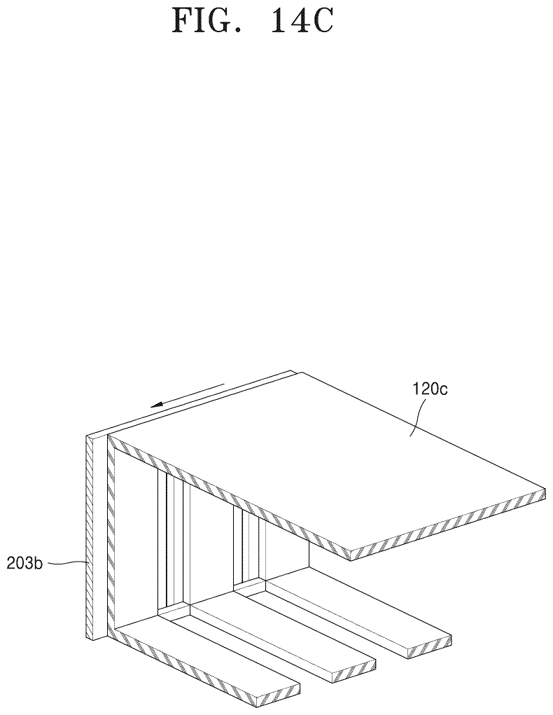

Referring to FIG. 10, a movable ring 203 may have a ring shape surrounding a second side partitioning wall 208 of the restriction ring 120c at an outer side portion of the restriction ring 120c. The movable ring 203 may be formed on the second side partitioning wall 208 of the restriction ring 120c. The restriction ring 120c may have a C-shaped cross-section on a vertical plane passing through the central axis. In this case, a lower surface of the restriction ring 120c may have third grooves 209 having a certain interval and the second side partitioning wall 208 of the restriction ring 120c may have fourth grooves 210 having the interval (see FIG. 12B, FIG. 12C, FIG. 14B, and FIG. 14C), (see FIG. 12B, FIG. 12C, FIG. 14B, and FIG. 14C), and the interval may between about 0.1 cm to about 2 cm.

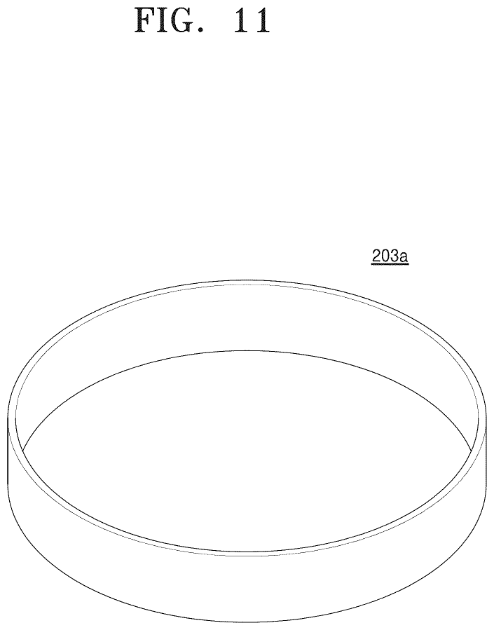

Operations of the actuator 190 and the movable ring 203 of the plasma processing apparatus 100c shown in FIG. 10 are described in detail herein with reference to FIGS. 11, FIG. 12A, FIG. 12B, FIG. 12C, FIG. 13, FIG. 14A, FIG. 14B, and FIG. 14C.

FIG. 11 is a perspective view of a movable ring 203a used in the plasma processing apparatus 100c of FIG. 10, according to an embodiment, and FIG. 12A, FIG. 12B, and FIG. 12C are perspective views for describing an operation of the movable ring 203a of FIG. 11.

Referring to FIG. 11, the movable ring 203a may have a ring shape fully surrounding the second side partitioning wall 208 of the restriction ring 120c at the outer side portion of the restriction ring 120c. FIG. 12A is a perspective view schematically illustrating a portion of the movable ring 203a of FIG. 11, and FIG. 12B and FIG. 12C are perspective views for describing an operation of the movable ring 203a.

Referring to FIG. 12B and FIG. 12C, an open-close ratio of the second side partitioning wall 208 of the restriction ring 120c covered by the movable ring 203a may be adjusted by moving the movable ring 203a upward and downward. The movable ring 203a may be moved upward and downward by the actuator 190 (see FIG. 1).

When the movable ring 203a fully surrounds the second side partitioning wall 208 of the restriction ring 120c (see FIG. 12B), air current leaked out from the internal space surrounded by the restriction ring 120c flows through the third grooves 209 of the lower surface of the restriction ring 120c. However, when the movable ring 203a moves upward (see FIG. 12C), air current leaked out from the internal space surrounded by the restriction ring 120c flows through both the third grooves 209 of the lower surface and the fourth grooves 210 of the second side partitioning wall 208 of the restriction ring 120c. By using this, the flow and density of air current in the internal space surrounded by the restriction ring 120c may be controlled by up-down movement of the movable ring 203a.

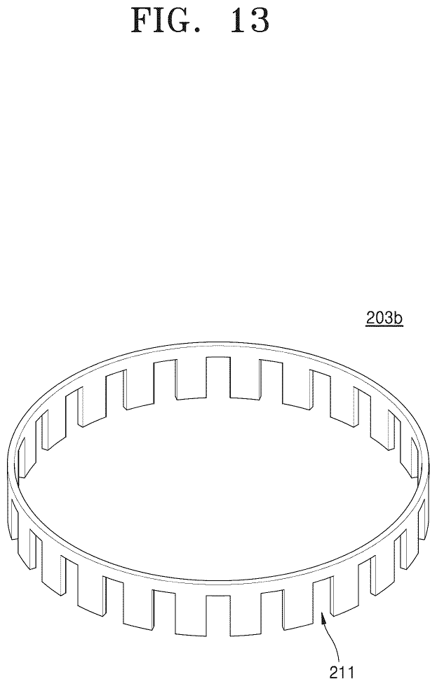

FIG. 13 is a perspective view of a movable ring 203b used in the plasma processing apparatus 100c of FIG. 10, according to another embodiment, and FIG. 14A, FIG. 14B, and FIG. 14C are perspective views for describing an operation of the movable ring 203b of FIG. 13.

Referring to FIG. 13, the movable ring 203b may have a ring shape surrounding the second side partitioning wall 208 of the restriction ring 120c and include straight grooves 211 at a certain interval in a side portion thereof. The interval may be between about 0.1 cm to about 2 cm. The straight grooves 211 may extend to a lower portion of the movable ring 203b so that the lower portion of the movable ring 203b may be open, but the technical idea of the inventive concept is not limited thereto.

FIG. 14A is a perspective view schematically illustrating a portion of the movable ring 203b of FIG. 13, and FIG. 14B and FIG. 14C are perspective views for describing an operation of the movable ring 203b.

Referring to FIG. 14B and FIG. 14C, an open-close ratio of the second side partitioning wall 208 of the restriction ring 120c covered by the movable ring 203b may be adjusted by rotating the movable ring 203b. The movable ring 203b may be rotated by the actuator 190 (see FIG. 1).

When the straight grooves 211 of the movable ring 203a are mismatched with fourth grooves 210 formed in the second side partitioning wall 208 of the restriction ring 120c (see FIG. 14B), air current leaked out from the internal space surrounded by the restriction ring 120c flows through the third grooves 209 of the lower surface of the restriction ring 120c. When the straight grooves 211 of the movable ring 203a are matched with the fourth grooves 210 formed in the second side partitioning wall 208 of the restriction ring 120c (see FIG. 14C), air current leaked out from the internal space surrounded by the restriction ring 120c flows through both the third grooves 209 of the lower surface and the fourth grooves 210 of the second side partitioning wall 208 of the restriction ring 120c. By using this, the flow and density of air current in the internal space surrounded by the restriction ring 120c may be controlled by rotation of the movable ring 203b.

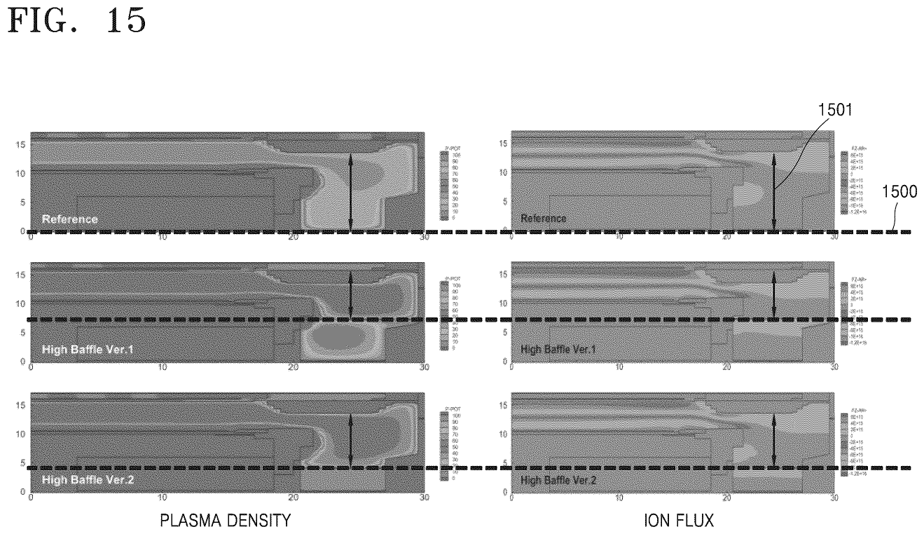

FIG. 15 illustrates simulation results showing a distribution of plasma density and ion flux according to the volume of an internal space of the process chamber surrounded by a restriction ring, according to the technical idea of the inventive concept.

Referring to FIG. 15, a dashed line, such as a first dashed line 1500, corresponds to a position of an opening of the restriction ring, and a length of an arrow, such a first arrow 1501, approximately indicates the volume of an internal space according to the position of the opening. Referring to FIG. 15, the density of plasma, the distribution of an electromagnetic field, ion flux, and the like may vary depending on positions of the opening.

When a word line cut process is performed, a word line structure may be formed like a wall, and during the process, a shadow effect may occur according to directivity of air current, such that a surface close to the flow of the air current may erode, and byproducts may accumulate on a surface away from the flow of the air current. Due to this shadow effect, a product having undergone the word line cut process has the possibility of having structural asymmetry, which may be considered a defect. When using a plasma processing apparatus according to the technical idea of the inventive concept, a direction of the air current may be actively controlled. The direction of the air current may be actively controlled to control, in real-time, an even flow of local air current and the distribution of a process when a wafer is processed. Thereby, a structural symmetry maybe achieved over the wafer and a defect may be prevented.

Introduction of the inventive concept in a process may enable active control of an air current inside a chamber, which may significantly affect the process. Active control of an air current inside a chamber may be useful in an atomic layer deposition (ALD) and atomic layer etching (ALE) process that is a technique of etching or depositing an atom-unit layer. According to an embodiment, by precisely controlling chemical species of plasma and the density-radius distribution of electrons and ions, the etching performance of an etching rate according to a distance from the center of a wafer, an aspect ratio, critical dimensions of an etching pattern, a profile of the etching pattern, a selectivity, and the like may be locally controlled. Therefore, the efficiency of a semiconductor process may be improved.

The technical idea of the inventive concept provides a plasma processing method including loading a substrate on a substrate chuck in a chamber of a plasma processing apparatus, injecting process gas into the chamber, and processing the substrate by supplying RF power to the chamber, wherein the processing of the substrate includes performing, at least once, an operation of adjusting a position of a movable ring.

Herein, the plasma processing apparatus may correspond to one of the plasma processing apparatus 100a, the plasma processing apparatus 100b, or the plasma processing apparatus 100c described in the specification. Herein, the movable ring may correspond to one of the movable ring 201a, the movable ring 201b, the movable ring 202, the movable ring 203a, and the movable ring 203b described in the specification.

The operation of adjusting the position of the movable ring may include a rotating motion for rotating the movable ring clockwise or counterclockwise. The operation of adjusting the position of the movable ring may include an up-down motion for moving the movable ring upward and downward. Herein, the operation of adjusting the rotating motion or the up-down motion of the movable ring may be performed in response to an operating command of an actuator. The actuator may sense the plasma distribution inside the chamber and provide the operating command to the movable ring based on a result of analyzing the plasma distribution. By the operating command, plasma inside the chamber may be spatially and/or temporally controlled. The actuator may correspond to the actuator 190 described in the specification.

While the inventive concept has been particularly shown and described with reference to embodiments thereof, it will be understood that various changes in form and details may be made therein without departing from the spirit and scope of the following claims.

What is claimed is:

1. A plasma processing apparatus comprising:
a substrate chuck in a chamber;
a restriction ring surrounding an outer perimeter of the substrate chuck;
a movable ring on the restriction ring; and
an actuator configured to move the movable ring,
wherein grooves formed in the restriction ring are opened or closed by movement of the movable ring.

2. The plasma processing apparatus of claim 1, wherein the movable ring has a ring shape extending along a side surface of the substrate chuck and comprises radial straight grooves disposed at an interval.

3. The plasma processing apparatus of claim 2, wherein the interval is between about 0.1 cm to about 2 cm.

4. The plasma processing apparatus of claim 1, wherein the movable ring alternately comprises a set of radial straight grooves and a fan-shaped groove.

5. The plasma processing apparatus of claim 1, wherein the actuator is configured to rotate the movable ring to adjust an open-close ratio of a lower surface of the restriction ring covered by the movable ring.

6. The plasma processing apparatus of claim 1, wherein the restriction ring comprises a side partitioning wall and an upper cover, and the movable ring has an L shape by further comprising a side wall formed on the side partitioning wall of the restriction ring.

7. The plasma processing apparatus of claim 6, wherein a lower surface of the movable ring has a ring shape with straight grooves disposed at an interval.

8. The plasma processing apparatus of claim 7, wherein the interval is between about 0.1 cm to about 2 cm.

9. The plasma processing apparatus of claim 6, wherein the actuator is configured to move the movable ring upward and downward to adjust an internal volume of a space surrounded by the restriction ring.

10. The plasma processing apparatus of claim 1, further comprising:
a sensor configured to sense plasma distribution inside the chamber; and
a plasma generator configured to control an amount of plasma introduced into the chamber, based on a result sensed by the sensor.

11. A plasma processing apparatus comprising:
a substrate chuck in a chamber and configured to receive a substrate;
a restriction ring surrounding an outer perimeter of the substrate chuck;
a movable ring having a ring shape surrounding a side partitioning wall of the restriction ring at an outer side portion of the restriction ring; and
an actuator configured to move the movable ring,
wherein grooves formed in the restriction ring are opened or closed by movement of the movable ring.

12. The plasma processing apparatus of claim 11, wherein the actuator is configured to move the movable ring upward and downward to adjust an open-close ratio of the side partitioning wall of the restriction ring covered by the movable ring.

13. The plasma processing apparatus of claim 11, wherein each of the side partitioning wall of the restriction ring and a side portion of the movable ring comprises straight grooves disposed at an interval.

14. The plasma processing apparatus of claim 13, wherein the interval is between about 0.1 cm to about 2 cm.

15. The plasma processing apparatus of claim 13, wherein the actuator is configured to move the movable ring to adjust an open-close ratio of the side partitioning wall of the restriction ring covered by the movable ring.

16. The plasma processing apparatus of claim 11, further comprising:
a sensor configured to sense plasma distribution inside the chamber; and
a plasma generator configured to control an amount of plasma introduced into the chamber, based on a result sensed by the sensor.

17. A plasma processing apparatus comprising:
a substrate chuck in a chamber;
an electrode configured to apply a radio frequency (RF) power to a process gas;
a restriction ring surrounding an outer perimeter of the substrate chuck; and
a movable ring on the restriction ring,
wherein the movable ring moves, at least once, when the RF power is applied to the process gas in the chamber.

18. The plasma processing apparatus of claim 17, wherein the movable ring rotates to adjust an open-close ratio of a space inside the chamber.

19. The plasma processing apparatus of claim 17, wherein the movable ring performs an up-down motion to move upward or downward inside the chamber.

20. The plasma processing apparatus of claim 17, further comprising an actuator, wherein the actuator senses a plasma distribution inside the chamber and provides an operating command to the movable ring based on a result of sensing the plasma distribution.
